(19) United States
(12) Patent Application Publication
(10) Pub. No.: US 2009/0218682 A1
(43) Pub. Date: Sep. 3, 2009

(54) SEMICONDUCTOR CHIP

(76) Inventor: Nils LUNDBERG, Hollviken (SE)

Correspondence Address: WARREN A. SKLAR (SOER);RENNER, OTTO, BOISSELLE & SKLAR, LLP, 1621 EUCLID AVENUE, 19TH FLOOR, CLEVELAND, OH, 44115, US

(21) Appl. No.: 12/040,984

(22) Filed: Mar. 3, 2008

(51) Int. Cl. H01L 23/34

(52) U.S. Cl. 257/723; 257/E25.006

(57) ABSTRACT

An integrated circuit package comprising at least one semiconductor chip of a first material, wherein the semiconductor chip comprises an active part and a passive part that is connected to each other, the passive part comprises at least one cavity, the at least one cavity is filled with a filler of a second material, and the thermal conductivity of the second material is higher than the thermal conductivity of the first material.

### TECHNICAL FIELD

This invention relates to an integrated circuit package comprising at least one semiconductor chip.

### BACKGROUND ART

The first commercially attractive cellular phones or terminals were introduced in the market at the end of the 1980's. Since then, a lot of effort has been made in making smaller radio communication terminals, with much help from the miniaturisation of electronic components and the development of more efficient batteries. Today, numerous manufacturers offer pocket-sized radio communication terminals with a wide variety of capabilities and services.

The development of new applications and games increases the demand for a higher performance of an integrated circuit package. As the speed and capacity is increasing, the heat generated in the semiconductor chip also increases. Further, as the size of the integrated circuit packages and semiconductor chips is decreasing, the silicon area that can contribute to dissipating heat also decreases. When the heat in a semiconductor chip is increased, the performance and operating life of the semiconductor chip decreases.

For these and other reasons, there is a need for the present invention.

### SUMMARY OF THE INVENTION

An integrated circuit package defined in claim 1 is provided according to the present invention.

More specifically the invention relates to an integrated circuit package comprising at least one semiconductor chip of a first material, wherein the semiconductor chip comprises an active part and a passive part that is connected to each other, the passive part comprises at least one cavity, the at least one cavity is filled with a filler of a second material, and the thermal conductivity of the second material is higher than the thermal conductivity of the first material.

An integrated circuit package according to this has the advantage of that the ability of dissipating heat from the semiconductor chip could be enhanced without the need of changing the active part of the semiconductor chip.

A further advantage is that the outer dimensions of the semiconductor chip, and thereby also the integrated circuit package, not have to be increased to increase the dissipation of heat.

Another advantage is that the capacity and the speed of the semiconductor chip and the integrated circuit package could be enhanced without increasing the dimensions of the semiconductor chip.

The at least one cavity can extend from a position at a heat generating position on the active part, which will generate heat during use, to an outer surface of the passive part. By doing this the advantages of that the dissipating of heat is increased in positions where it is the most needed. The location of a heat generating position on a semiconductor chip could either be calculated in advance or iterated by trial and error for a specific integrated circuit package.

A further advantage is that the fillers will function as a chimney and dissipate the heat away from the heat generating position.

To enhance the ability to dissipate heat from the place where it is generated, the dimensions of the cross section of the cavity can correspond to the dimensions of the cross section of the heat generating position.

The filler can be adapted to dissipate heat away from the heat generating position.

The first material can be Silicon (Si) or Germanium (Ge).

The second material can be silicon carbide (SiC) or diamond, which are a good material for dissipating heat.

The integrated circuit package can comprise an enclosure, wherein the enclosure can surround the semiconductor chip and can be adapted to dissipate heat assisted from the filler. By doing this the advantages of that the ability of dissipating heat away from the active part could be even further enhanced.

The enclosure can be made of epoxy and silicon carbide (SiC) or epoxy and diamond.

The integrated circuit package can comprise a routing substrate, wherein the at least one semiconductor chip is arranged on the routing substrate.

### BRIEF DESCRIPTION OF THE DRAWINGS

The features and advantages of the present invention will be more apparent from the following description of preferred embodiments with reference to the accompanying drawings, in which

FIG. 1 schematically illustrates a cross section of an integrated circuit package according to one embodiment of the invention.

FIG. 2 schematically illustrates a cross section of an integrated circuit package according to a second embodiment of the invention.

### DETAILED DESCRIPTION

It should be emphasised that the term comprising or comprises, when used in this description and in the appended claims to indicate included features, elements or steps, is in no way to be interpreted as excluding the presence of other features elements or steps than those expressly stated.

In the following description reference is made to the accompanying drawings. In this regard directional terminology, such as “top”, “bottom”, “front”, “back” etc, is used with reference to the orientation of the figures being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present protection. The following detailed description is not to be taken in a limiting sense, and the scope of the present invention is defined by the appended claims.

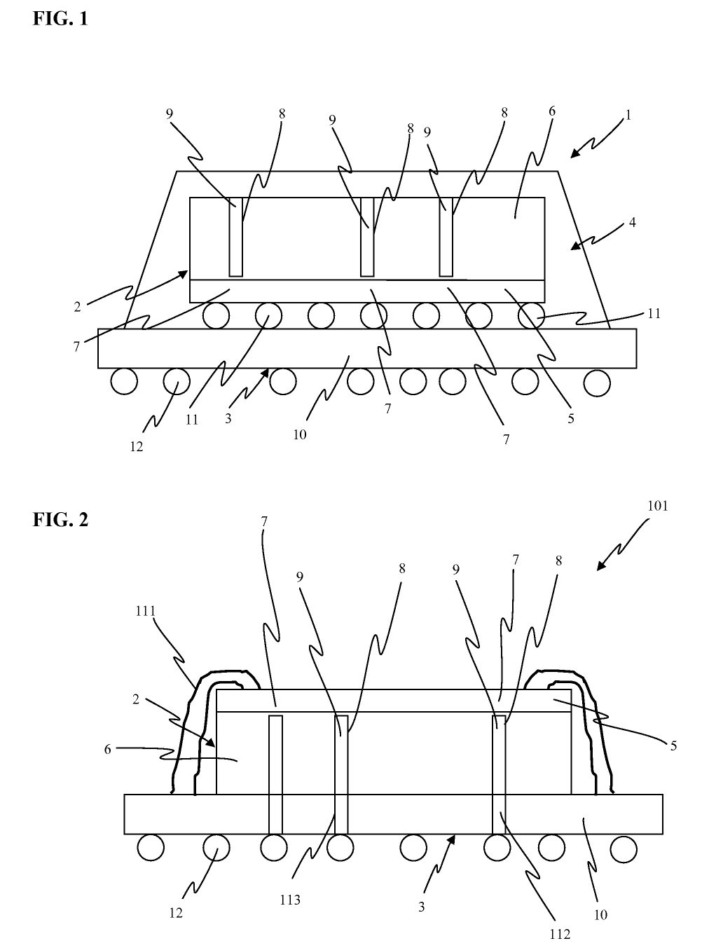

FIG. 1 discloses an integrated circuit package 1 according to a first embodiment of the invention comprising a semiconductor chip 2, a routing substrate 3 and an enclosure 4.

The function of an integrated circuit package and a semiconductor chip as such is known in the prior art and will for this reason not be described further herein.

The semiconductor chip 2 is made of one piece and comprises an active part 5 and a passive part 6. The passive part 6 is positioned on top of the active part 5. The semiconductor chip 2 is made of a first material. The first material could be silicon (Si) or germanium (Ge).

The active part 5 comprises in the shown embodiments three heat generating positions 7. A heat generating position 7 could for instance appear in a position where a lot of electric activities occur. A high current or high frequencies in a position within the active part could be a heat generating position. A heat generating position is also known as a “hot spot”. The location of a heat generating position on a semiconductor chip could either be calculated in advance or iterated by trial and error for a specific integrated circuit package. The function and components of the active part 5 is known in prior art and will thus not be described further herein.

The passive part 6 comprises in the shown embodiments three cavities 8. The cavities 8 extend from an upper surface 9 of the passive part 6 towards the active part 5. The cross section of the cavity 8 have a shape that corresponds to the shape of a heat generating position 7, it could for instance have a circular or a rectangular shape. Each cavity 8 is arranged in a close vicinity to each of the heat generating positions 7. Each cavity 8 is filled with a filler 9. The filler 9 is made of a second material. The second material could be silicon carbide (SiC) or diamond. The second material has a thermal conductivity that is higher than the thermal conductivity of the first material.

The routing substrate 3 comprises a board 10, internal contacts 11 and external contacts 12. The routing substrate 3 could for instance be a printed circuit board or a ceramic Low Tempered Co-fired Ceramic substrate (LTCC substrate).

The enclosure 4 surrounds the semiconductor chip 2. The enclosure is made of a third material. The third material could be a mixture of epoxy and silicon carbide (SiC) or a mixture of epoxy and diamond. The third material has a thermal conductivity that is equal to or higher than the thermal conductivity of the first material.

The semiconductor chip 2 is arranged on to the routing substrate 3. The active part 5 of the semiconductor chip is directed towards the routing substrate 3. The internal contacts 11 are connected to the active part 5 of the semiconductor chip 2. The enclosure 4 surrounds the semiconductor chip 2 and is connected to the routing substrate 3. The enclosure 4 protects the semiconductor chip 2 from the surrounding and from dust and particles. The integrated circuit package 1 could be connected to other integrated circuit packages or printed circuit boards via the external contacts 12.

When the integrated circuit package 1 is arranged in a device (not disclosed), such as a mobile telephone, and is active, heat is generated in the active part 5 of the semiconductor chip 2. The most heat is generated in the heat generating positions 7. The cavities 8 and the fillers 9 are arranged close to the heat generating positions 7. As the thermal conductivity of the filler 9 is higher than the thermal conductivity of the active and passive part 5, 6 of the semiconductor chip 2, the generated heat will be transferred away from a heat generating position 7 by the filler 9. The filler 9 will thus dissipate the heat away from the heat generating position 7 in an effective way. The heat is thereafter transferred from the filler 9 to the enclosure 4. By doing this the ability of the filler 9 to dissipate the heat will increase. Thereafter the heat in the enclosure 4 will dissipate into the surroundings. The enclosure 4 has a relatively large area that is exposed to the surroundings.

FIG. 2 discloses an integrated circuit package 101 according to a second embodiment of the invention. The integrated circuit package 101 comprises a semiconductor chip 2 and a routing substrate 3.

The routing substrate 3 comprises a board 10, internal contacts 111, external contacts 12 and holes 112. The routing substrate 3 could for instance be a printed circuit board or a ceramic Low Tempered Co-fired Ceramic substrate (LTCC substrate). The routing substrate 3 comprise 3 holes 112 in the shown embodiment. The hole 112 could be a through hole via (THV). The walls 113 of the holes 112 could be covered of a fourth material. As an alternative could the holes 112 be filled with the fourth material. The fourth material could correspond to the second material.

The semiconductor chip 2 corresponds to the semiconductor chip 2 in FIG. 1. The semiconductor chip 2 is arranged on the routing substrate 3. The active part 5 of the semiconductor chip 2 is directed away from the routing substrate 3. The passive part 6 is directed towards the semiconductor chip 3. The semiconductor chip 2 is arranged in the routing substrate 3 such that the cavities 8 and the fillers 9 is arranged on the holes 112 of the routing substrate 3. The fillers 9 makes contact with the walls 113 of the holes 112. The active part 5 of the semiconductor chip 2 is connected to the internal contacts 111 of the routing substrate 3. The integrated circuit package 101 could be connected to other integrated circuit packages or printed circuit boards via the external contacts 12.

When the integrated circuit package 101 is arranged in a device (not disclosed), such as a mobile telephone, and is active, heat is generated in the active part 5 of the semiconductor chip 2. The most heat is generated in the heat generating positions 7. The heat is transferred away from the heat generating positions 7 by that the filler 9 transports the heat away from the heat generating position towards the routing substrate 3. As the heat reaches the routing substrate 3 the heat will be transferred from the filler to the walls 113 of the holes 112. Thereafter the heat will be dissipated in to the surroundings. In addition to this heat transfer, heat from the active part 5 will be dissipated directly into the surroundings on the side of the active part 5 that is directed away from the routing substrate 3.

In a further embodiment the integrated circuit package in FIG. 2 further could comprise a enclosure. The enclosure will further enhance the dissipation of heat away from the heat generating positions.

One way of obtaining the cavities in the passive part of a semiconductor chip is by etching.

The principles of the present invention have been described in the abovementioned by examples of embodiments or modes of operations. However, the invention should not be construed as being limited to the particular embodiments discussed above, which are illustrative rather than restrictive, and it should be appreciated that variations may be made in those embodiments by persons skilled in the art, without departing from the scope of the present invention as defined by the appended claims.

1. An integrated circuit package comprising at least one semiconductor chip of a first material, wherein
the semiconductor chip comprises an active part and a passive part that is connected to each other,
the passive part comprises at least one cavity,
the at least one cavity is filled with a filler of a second material, and
the thermal conductivity of the second material is higher than the thermal conductivity of the first material.

2. The integrated circuit package according to claim 1, wherein the at least one cavity extends from a position at a heat generating position on the active part, which will generate heat during use, to an outer surface of the passive part.

3. The integrated circuit package according to claim 1, wherein the dimensions of the cross section of the cavity corresponds to the dimensions of the cross section of the heat generating position.

4. The integrated circuit package according to claim 1, wherein the filler is adapted to dissipate heat away from the heat generating position.

5. The integrated circuit package according to claim 1, wherein the first material is silicon (Si) or Germanium (Ge).

6. The integrated circuit package according to claim 1, wherein the second material is silicon carbide (SiC).

7. The integrated circuit package according to claim 1, comprising an enclosure, wherein the enclosure surrounds the semiconductor chip and is adapted to dissipate heat away from the active part and the filler.

8. The integrated circuit package according to claim 7, wherein the enclosure is made of epoxy and of silicon carbide (SiC).

9. The integrated circuit package according to claim 7, wherein the enclosure is made of epoxy and of diamond.

10. The integrated circuit package according to claim 1, comprising a routing substrate, wherein the at least one semiconductor chip is arranged on the routing substrate.
